(19) United States
(12) Patent Application Publication
(10) Pub. No.: US 2014/0162054 A1
(43) Pub. Date: Jun. 12, 2014

(54) INTERPOSER LAYER FOR ENHANCING ADHESIVE ATTRACTION OF POLY(P-XYLYLENE) FILM TO SUBSTRATE

(71) Applicant: Industrial Technology Research Institute, Hsinchu (TW)

(72) Inventors: Tai-Hung Chen, Taipei City (TW); Chun-Hao Chang, Tainan City (TW); Li-Wen Lai, Taichung City (TW); Kun-Wei Lin, Tainan City (TW)

(73) Assignee: Industrial Technology Research Institute, Hsinchu (TW)

(21) Appl. No.: 14/102,402

(22) Filed: Dec. 10, 2013

(30) Foreign Application Priority Data
Dec. 11, 2012 (TW) 101146536

(51) Int. Cl. C09J 183/04; B32B 17/10; H01L 51/52; B32B 7/12

(52) U.S. Cl. CPC C09J 183/04; B32B 7/12; B32B 17/1055; H01L 51/52
USPC 428/336; 427/489; 428/448; 428/428; 428/426

(57) ABSTRACT

An embodiment of the present disclosure provides a laminate structure, including a substrate having a surface; a poly(p-xylylene) film over the surface of the substrate; and an interposer layer between the substrate and the poly(p-xylylene) film. The interposer layer is bonded to both the substrate and the poly(p-xylylene) film in a covalent manner, and a ratio of Si—C bonds and Si—X bonds in the interposer layer is in a range from about 0.3 to about 0.8, wherein X is O or N.

### CROSS REFERENCE TO RELATED APPLICATION

The present application is based on, and claims priority from, Taiwan Application Serial Number 101146536, filed on Dec. 11, 2012, the disclosure of which is hereby incorporated by reference herein in its entirety.

### TECHNICAL FIELD

The technical field relates to electronic devices, and in particular to a laminate structure having a poly(p-xylylene) film and a method for forming the laminate structure.

### BACKGROUND

Poly(p-xylylene), an organic polymer material, has high resistance to acid and base, high transparency and high dielectric constant and is often used as insulating material in electronic devices. Substrates that are used in electronic devices often have a metal surface or a semiconductor surface. For example, a printed circuit board (PCB) substrate has a copper layer or copper traces on its surface. The metal surface and the semiconductor surface are each formed of an inorganic material that exhibits far different properties from organic materials. Therefore, a poly(p-xylylene) film has poor adhesive attraction to the metal surface or the semiconductor surface because the bonding between poly(p-xylylene) film and the metal surface or the semiconductor surface is hetero-bonding. In other words, the poly(p-xylylene) film has limited uses in the more advanced and size-reduced electronic devices even if it has such good properties for being used as an insulating layer.

Recently, methods for enhancing the adhesive attraction of the poly(p-xylylene) film to metal surfaces have been developed. One of these methods is a wet cleaning method. The wet cleaning method includes wet cleaning the metal surface using silane coupling agents to the metal surface; heating the metal surface to at least about 90° C. for bonding the silane coupling agents to the metal surface; washing out non-bonded silane coupling agents with a suitable solvent; and drying the metal surface. However, the wet cleaning method may damage tiny electronic traces on the metal surface, and the adhesive attraction will be degraded while the bonds between the silane coupling agents and the metal surface age with time.

Another method, called a dry cleaning method, has been also developed, which includes activating the metal surface by plasma for facilitating to the direct coating of the poly(p-xylylene) film onto the metal surface. However, the adhesive attraction of the poly(p-xylylene) film to the metal surface is only slightly enhanced by the dry cleaning method.

### SUMMARY

A detailed description is given in the following embodiments with reference to the accompanying drawings.

An embodiment of the present disclosure provides a laminate structure, including a substrate having a surface; a poly(p-xylylene) film over the surface of the substrate; and an interposer layer between the substrate and the poly(p-xylylene) film, wherein the interposer layer is bonded to both the substrate and the poly(p-xylylene) film in a covalent manner, wherein a ratio of Si—C bonds and Si—X bonds in the interposer layer is in a range from about 0.3 to about 0.8, wherein X is O or N.

An embodiment of the present disclosure also provides a method for forming a laminate structure, including: providing a substrate that has a surface; introducing a silane coupling agent to a deposition chamber for forming an interposer layer over the surface of the substrate by plasma enhanced chemical vapor deposition (PECVD), wherein the gas in the deposition chamber comprises only a silane group agent during the PECVD; thermal cracking poly(p-xylylene) oligomers to poly(p-xylylene) monomers that carry radicals; and introducing the poly(p-xylylene) monomers to the deposition chamber to polymerize to a poly(p-xylylene) film, wherein the poly(p-xylylene) film is bonded to the interposer layer in a covalent manner.

An embodiment of the present disclosure also provides a luminescent device, including: a substrate having a surface; a luminescent component over the surface of the substrate; a poly(p-xylylene) film over the surface of the substrate and covering the luminescent component; an interposer layer between the luminescent component and the substrate, wherein the interposer layer is bonded to both the substrate and the poly(p-xylylene) film in a covalent manner, wherein a ratio of Si—C bonds and Si—X bonds in the interposer layer is in a range from about 0.3 to about 0.8, wherein X is O or N; and a first barrier layer covering the poly(p-xylylene) film.

### BRIEF DESCRIPTION OF DRAWINGS

The present disclosure can be more fully understood by reading the subsequent detailed description and examples with references made to the accompanying drawings, wherein:

FIGS. 1A to 1C show cross-sectional views of intermediate stages of a method of forming a laminate structure containing a poly(p-xylylene) film, in accordance with an exemplary embodiment.

FIGS. 2A to 2E show cross-sectional views of intermediate stages of a method of forming a luminescent device, in accordance with an exemplary embodiment.

FIG. 3 shows a cross-sectional view of a luminescent device that has contaminant particles adhered to it, in accordance with an exemplary embodiment.

FIGS. 4A and 4B show FTIR spectrums of an interposer layer, in accordance with some exemplary embodiments.

FIGS. 5A and 5B, respectively, show photographs luminescent devices with and without a poly(p-xylylene) film in operation.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

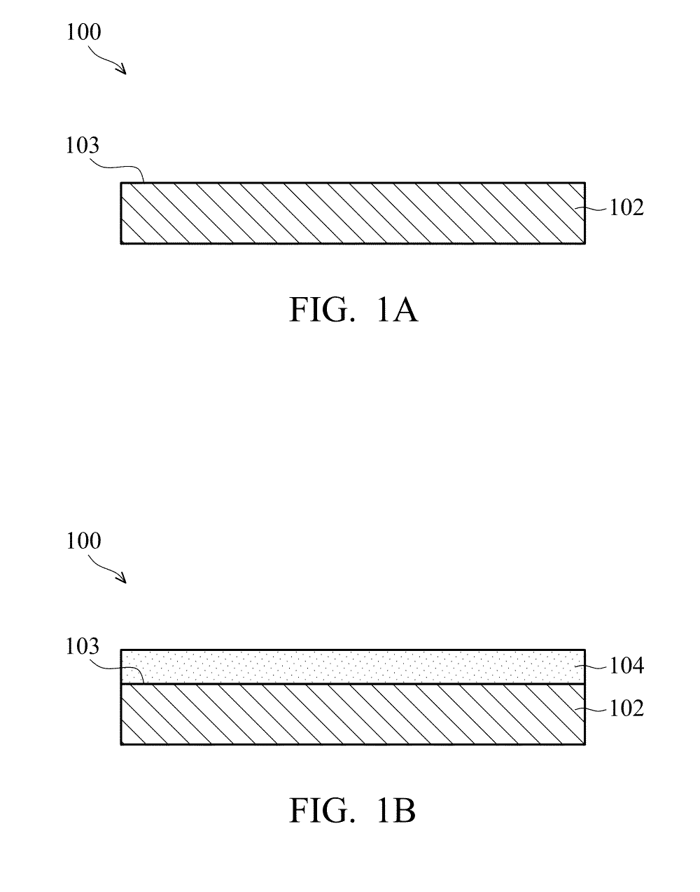

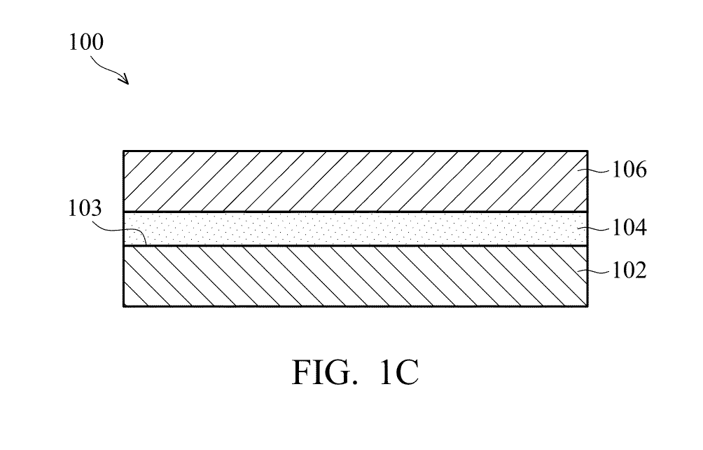

FIGS. 1A to 1C show cross-sectional views at intermediate stages of a method of fabricating a laminate structure 100 containing a poly(p-xylylene) film, in accordance with an exemplary embodiment of the present disclosure. Referring to FIG. 1A, a substrate 102 having a surface 103 is provided. The substrate 102 may be a metal substrate, a semiconductor substrate, a metal oxide substrate, a glass substrate or a plastic substrate. Alternatively, the substrate 102 may be any suitable substrate having the surface 103, and the surface 103 is a metal surface, a semiconductor surface, a metal oxide surface, a glass surface or a plastic surface. In some embodiments, the metal surface includes copper, titanium, aluminum, alloys thereof, or stainless steel. The metal oxide surface may include indium tin oxide (ITO), zinc oxide (ZnO), indium gallium zinc oxide (IGZO), gallium zinc oxide (GZO), aluminum zinc oxide (AZO) or a combination thereof. The semiconductor surface may include silicon or other suitable semiconductor materials. The glass surface may include strengthened glass, glass fiber or a combination thereof. The plastic surface may include polyimide (PI), polyethylene terephthalate (PET), polyethylene naphthalate (PEN), polyethersulfone (PES), polycarbonate (PC) or a combination thereof.

Afterwards, referring to FIG. 1B, an interposer layer 104 is deposited on the surface 103 of the substrate 102. In an embodiment, the interposer layer 104 may be deposited by plasma-enhanced chemical vapor deposition (PECVD). A silane coupling agent may be used as deposition source in the PECVD. Example silane coupling agents include hexamethyldisiloxane (HMDSO) and hexamethyldisilazane (HMDS). The interposer layer 104 may have a thickness ranging from about 30 nm to about 300 nm. In the present embodiment, the interposer layer 104 may be bonded to the substrate 102. In addition, a ratio of Si—C bonds and Si—X bonds in the interposer layer 104 is in a range from about 0.3 to 0.8, where X is O or N.

In the present embodiment, the ratio of Si—C bonds and Si—X bonds may be controlled by the deposition parameters used in the PECVD, such as gas atmosphere and flow rate. For example, during the PECVD, the gas introduced to a deposition chamber substantially includes only the silane coupling agent. The flow rate of the silicon coupling agent may be in a range from about 10 sccm to about 200 sccm. In addition, the PECVD may be performed under a power ranging from about 50 W to about 1000 W and a pressure ranging from about 1 mTorr to about 1000 mTorr. The PECVD may be performed for about 1 min to about 60 mins. A surface temperature of the substrate 102 may be maintained at room temperature during the PECVD, which may result in improving or preventing an aging problem of the interposer layer 104 and the surface 103 as well as making the tiny electronic traces (if existing) on the surface 103 suffer from less damage.

In an optional embodiment, the surface 103 of the substrate 102 is activated by a plasma treatment before the deposition of the interposer layer 104. For example, the plasma treatment may include introducing argon to a vacuum chamber, and bombarding the surface 103 under a power of about 50 W to about 1000 W and a temperature of about 20° C. to about 100° C. for about 1 to about 3 minutes. It should be noted that the plasma treatment is not suitable for being performed too long, for preventing the surface 103 from being damaged. The plasma treatment may induce the formation of dangling bonds on the surface 103, which can help form covalent bonds between substrate 102 and the interposer layer 104. For example, the plasma treatment may induce the formation of carbon dangling bonds on the surface 103 when the surface 103 is the plastic surface.

Afterwards, referring to FIG. 1C, a poly(p-xylylene) film 106 is formed on the interposer layer 104. In an embodiment, the poly(p-xylylene) film 106 is deposited on the interposer layer 104 by chemical vapor deposition (CVD). In some embodiments, the CVD process include placing a solid powder of p-xylylene oligomers (such as dimers) in a vaporizing chamber with heating to above about 150 degrees Celsius for vaporizing the p-xylylene oligomers to a gas; introducing the gas of p-xylylene oligomers to a pyrolysis chamber for thermal-cracking the oligomers into monomers at a temperature above about 600 degrees Celsius, where radicals are formed on the monomers; and then introducing the p-xylylene monomers into a deposition chamber where the substrate 102 coated with the interposer layer 104 is located within. The poly(p-xylylene) film 106 may be polymerized from the poly(p-xylylene) monomers and deposited on the interposer layer 104. In some embodiments, the CVD is performed at a room temperature and under a pressure of about 10 mTorr to about 50 mTorr. A surface temperature of the substrate 102 may be in a range from room temperature to about −40 degrees Celsius. In some embodiments, the poly(p-xylylene) film 106 includes Parylene-C, Parylene-D, Parylene-N, Parylene-F or a combination thereof. The poly(p-xylylene) film 106 may have a thickness ranging from about 0.2 μm to about 10 μm.

Covalent bonds, such as —Si—R—CH₂—CH₂ or —Si—O—R—CH₂—CH₂—, are also formed between the poly(p-xylylene) film 106 and with the —Si—R—CH₃ groups or the —Si—O—R—CH₃ groups of the interposer layer 104 during the polymerization of the p-xylylene monomers.

In other words, the interposer layer 104 and the poly(p-xylylene) film 106 may be covalently bonded via the following structure formula (I):

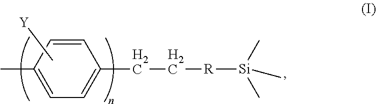

in which “n” is an integer greater than or equal to 1, Y is Cl or H, and “R” is −(CH₂)ₘ—, in which “m” is an integer from 0 to 500.

The poly(p-xylylene) film 106 may have obvious enhancement of the adhesive attraction to the substrate 102 since the poly(p-xylylene) film 106 is bonded to the interposer layer 104 in a covalent manner while the interposer layer 104 is bonded to the substrate 102 also in covalent manner. In addition, the silane groups may be prevented from forming a lattice-like structure when the ratio of the Si—C bonds and the Si—X bonds in the interposer layer 104 is in the range from about 0.3 to about 0.8. As such, more silane groups are available for forming the structure represented in the formula (I) with the poly(p-xylylene) film 106, thereby further improving the adhesive attraction to a desired level. For example, the adhesive attraction of the poly(p-xylylene) film 106 to the substrate 102 can reach level 5B (0% loss of coating) in a cross-cut tape adhesion test (1 mm cross 100 measures) according to the ASTM D 5539 standard test method.

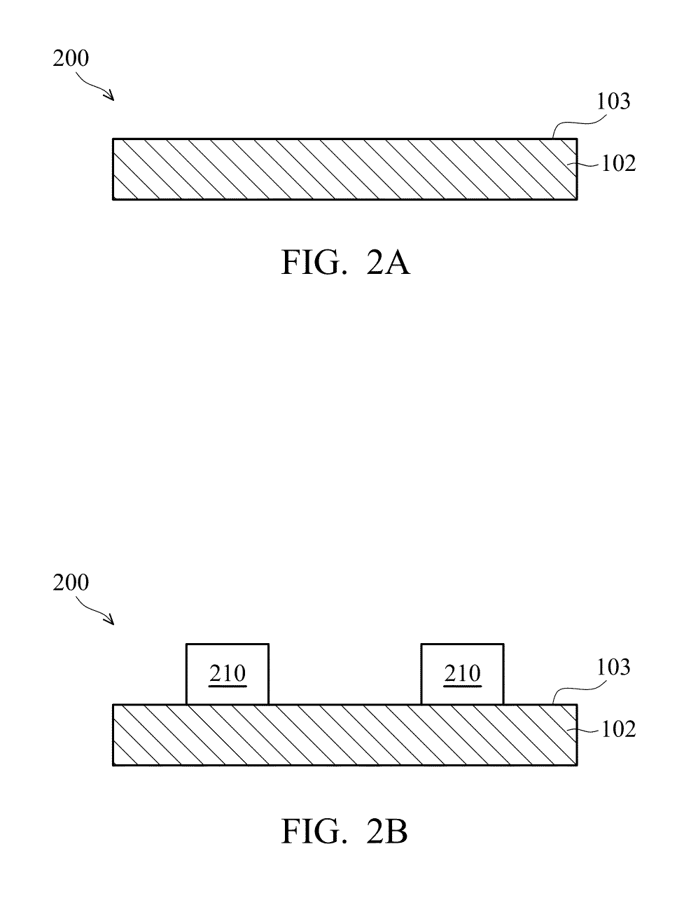

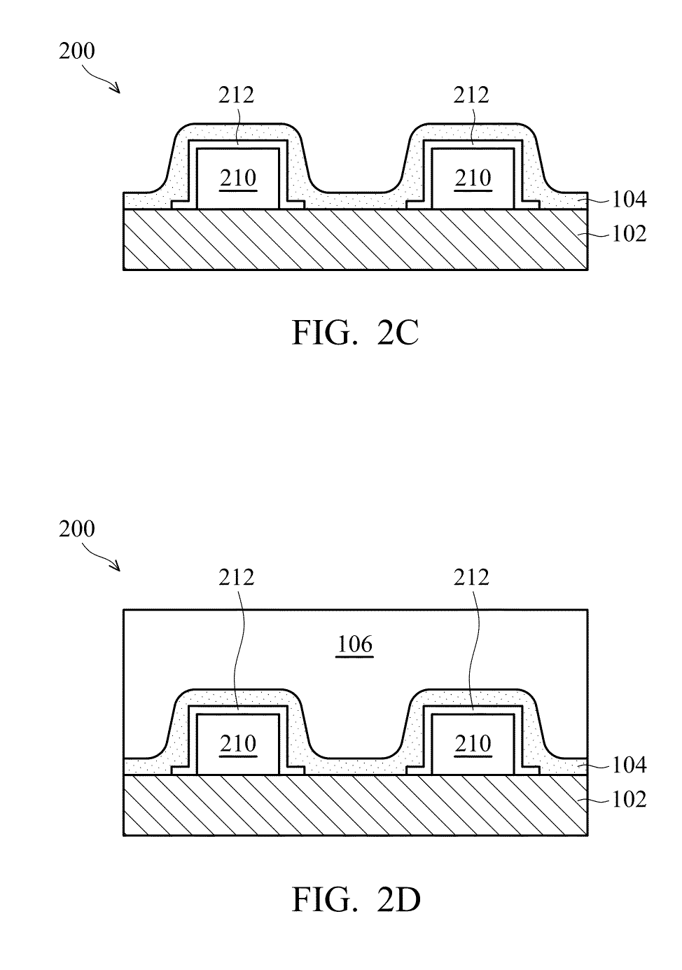

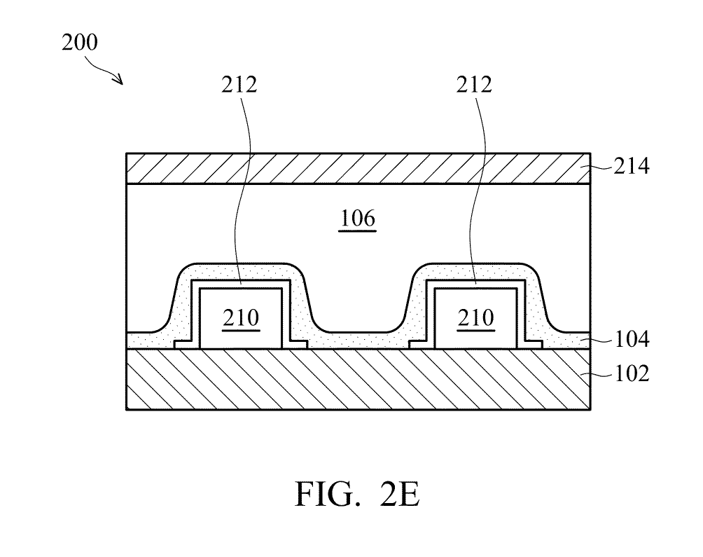

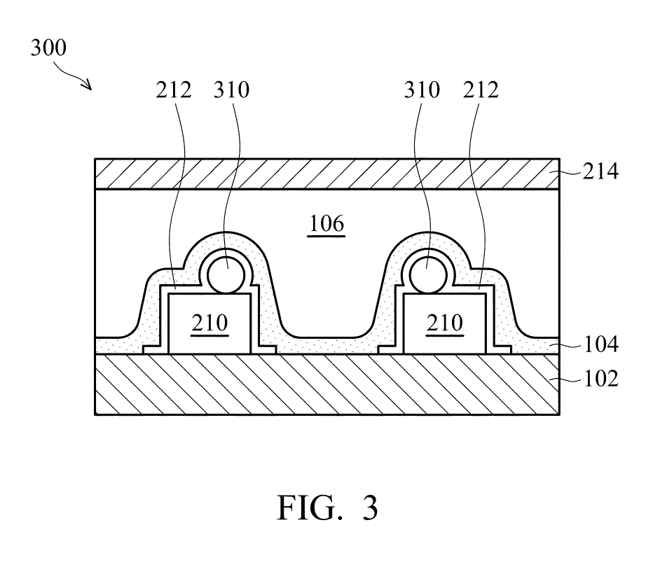

FIGS. 2A to 2E show cross-sectional views at intermediate stages of a method for fabricating a luminescent device, in accordance with some embodiments of the present disclosure. Referring to FIG. 2A, the substrate 102 is provided. As described above, the substrate 102 may be a metal substrate, a metal oxide substrate, a semiconductor substrate, a glass substrate or a plastic substrate. Alternatively, the substrate 102 may be any suitable substrate having a surface 103 made of metal, a metal oxide, a semiconductor, glass or plastic. In the present embodiments, the substrate 102 is the glass substrate.

Afterwards, referring to FIG. 2B, one or more luminescent components 210 are formed over the substrate 102. In some embodiments, the luminescent components 210 include an organic light emitting diode (OLED), light emitting diode (LED), laser diode (LD) or a combination thereof. The number of luminescent components 210 may be varied more or less according to design requirements although only two luminescent components 210 are shown in FIG. 2B. In addition, the luminescent components 210 may be arranged in an array form.

Afterwards, referring to FIG. 2C, the interposer layer 104 may be formed and cover the luminescent components 210 and the substrate 102. At least a portion of the interposer layer 104 is in direct contact with the surface 103 of the substrate 102. The interposer layer 104 may form covalent bonds with the substrate 102. For example, in the present embodiment, the interposer layer 104 is bonded to the substrate 102 via Si—O—Si bonds.

Furthermore, in an optional embodiment, a barrier layer 212 is formed on the luminescent components 210 before the formation of the interposer layer 104. The barrier layer 212 may cover the luminescent components 210. For example, the barrier layer 212 may cover an upper surface and sidewalls of the luminescent components 210 for preventing them from being damaged by oxygen and moisture intrusions. In some embodiments, the barrier layer 212 includes one or more organic sub-layers and/or one or more inorganic sub-layers. Each of the sub-layers may have a thickness ranging from about 30 nm to about 200 nm. For example, the inorganic sub-layers may include silicon oxide, titanium dioxide, titanium (II) oxide, silicon nitride, aluminum oxide, hafnium oxide, a combination thereof, or other transparency materials. The organic sub-layers may include polyurethane, polyamide, polyimide, polyolefins, benzocyclobutadiene, polynorbornene, epoxy resins, polyether, polyaniline or a combination thereof. Alternatively, the barrier layer 212 may be formed of an organic siloxane film. The organic siloxane film may be formed from the silane coupling agents, and a ratio of the Si—C bonds and Si—O bonds in the organic siloxane film is less than about 0.25. In an embodiment, the barrier layer 212 has a thickness ranging from about 300 nm to about 1000 nm and a water penetration ratio that is less than about 10⁻³ g/m² per day.

Afterwards, referring to FIG. 2D, the poly(p-xylylene) film 106 is formed on the interposer layer 104. The poly(p-xylylene) film 106 may include Parylene-C, Parylene-D, Parylene-N, Parylene-F or a combination thereof. In the present embodiment, the poly(p-xylylene) film 106 has a thickness ranging from about 0.2 μm to about 10 μm.

Afterwards, referring to FIG. 2E, a barrier layer 214 is formed over the poly(p-xylylene) film 106. The barrier layer 214 may include one or more organic sub-layers and/or one or more inorganic sub-layers. Each of the sub-layers may have a thickness ranging from about 30 nm to about 200 nm. For example, the inorganic sub-layers may include silicon oxide, titanium dioxide, titanium (II) oxide, silicon nitride, aluminum oxide, hafnium oxide, a combination thereof or other transparency materials. The organic sub-layers may include polyurethane, polyamide, polyimide, polyolefins, benzocyclobutadiene, polynorbornene, epoxy resins, polyether, polyaniline or a combination thereof. Alternatively, the barrier layer 214 may be formed of an organic siloxane film. The organic siloxane film may be formed from the silane coupling agents, and a ratio of the Si—C bonds and Si—O bonds in the organic siloxane film is less than about 0.25. In an embodiment, the barrier layer 214 has a thickness ranging from about 300 nm to about 1000 nm and a water penetration ratio that is less than about 10⁻³ g/m² per day.

Note that the steps as shown in FIGS. 2B to 2E and the transporting durations between the steps shall be operated under a substantially vacuum environment. It prevents the luminescent components 210 from being damaged by moisture or contaminants.

The poly(p-xylylene) film 106 is capable of being directly formed by the vapor deposition under the vacuum environment and is suitable for the packaging process of the luminescent components 210. The packaging process of the luminescent components 210 shall be performed under the vacuum environment from start to finish such that the luminescent components 210 are prevented from being damaged by the moisture or oxygen during a packaging process. The poly(p-xylylene) film 106 may have excellent step coverage and have a high thickness in a short period of time because it is polymerized from small molecules during the vapor deposition. The poly(p-xylylene) film 106 can effectively wrap the contaminant particles that are adhered onto the luminescent components 210 and reduce the possibility of the intrusion of the moisture and oxygen. In some embodiments, the contaminant particles have a size of few micrometers. The barrier layers 212 and 214 may also more or less wrap the contaminant particles. However, voids and bubbles are sometimes formed in the luminescent components 210 when the luminescent components 210 are only covered by the barrier layers 212 and/or 214, due to the low thickness and poor step coverage of the barrier layers 212 and/or 214. The poly(p-xylylene) film 106 may help successfully wrap the contaminant particles and cure the deficiency of the barrier layers 212 and 214, thereby increasing the reliability of the luminescent device 200.

For example, referring to FIG. 3, it shows a luminescent device 300 that has contaminant particles adhered to it. As shown in FIG. 3, the poly(p-xylylene) film can effectively cover the contaminant particles 310 resulting from its good step coverage and the sufficiently high thickness. The environmental moisture and oxygen are insulated from the luminescent components 210. In addition, the poly(p-xylylene) film 106 has the enhanced adhesive attraction to the substrate 102 due the presence of the interposer layer 104. Accordingly, the luminescent device 300 may still exhibit an improved performance even if the contaminant particles are adhered to it.

### Example 1

A SUS 304 stainless substrate was disposed in a vacuum deposition chamber. 100 sccm of Ar was introduced to the deposition chamber and a pressure in the deposition chamber maintained at 80 mTorr. RF plasma of 100 W and 13.56 MHz was applied to the surface of the stainless substrate for 1 minute. 100 sccm of HMDSO was then introduced to the deposition chamber and coated to the surface of the stainless substrate under a pressure of 40 mTorr and RF plasma of 100 W and 13.56 MHz for 10 minutes. An interposer layer was formed. The interposer layer had a thickness of about 120 nm, and a ratio of Si—C bonds and Si—O bonds in the interposer layer was about 0.3.

10 g of a solider powder of p-xylylene dimers was disposed in a vaporizing chamber and heated to 150 degrees Celsius to vaporize the p-xylylene dimers to gas. Afterwards, the gas of p-xylylene was introduced to a thermal cracking chamber that had a temperature of 650 degrees Celsius for being thermal-cracked to monomers. The p-xylylene monomers were then introduced to the deposition chamber that was at room temperature, and a poly(p-xylylene) film was deposited. The poly(p-xylylene) film had a thickness of about 1 μm.

### Example 2

The same operation as in Example 1 was repeated except that the 100 sccm of HMDSO was replaced with 150 sccm of HMDSO. In this Example, a ratio of Si—C bonds and Si—O bonds in the interposer layer was about 0.5.

### Example 3

The same operation as in Example 1 was repeated except that the 100 sccm of HMDSO was replaced with 200 sccm of HMDSO. In this Example, a ratio of Si—C bonds and Si—O bonds in the interposer layer was about 0.8.

### Example 4

The same operation as in Example 1 was repeated except that the 100 sccm of HMDSO was replaced with 30 sccm of Ar and 100 sccm HMDSO. In this Example, a ratio of Si—C bonds and Si—O bonds in the interposer layer was about 0.25.

### Example 5

The same operation as in Example 1 was repeated except that the 100 sccm of HMDSO was replaced with 160 sccm of N₂O and 100 sccm HMDSO. In this Example, a ratio of Si—C bonds and Si—O bonds in the interposer layer was about 0.07.

### Example 6

The same operation as in Example 1 was repeated except that the HMDSO was not introduced, and the interposer layer was not formed.

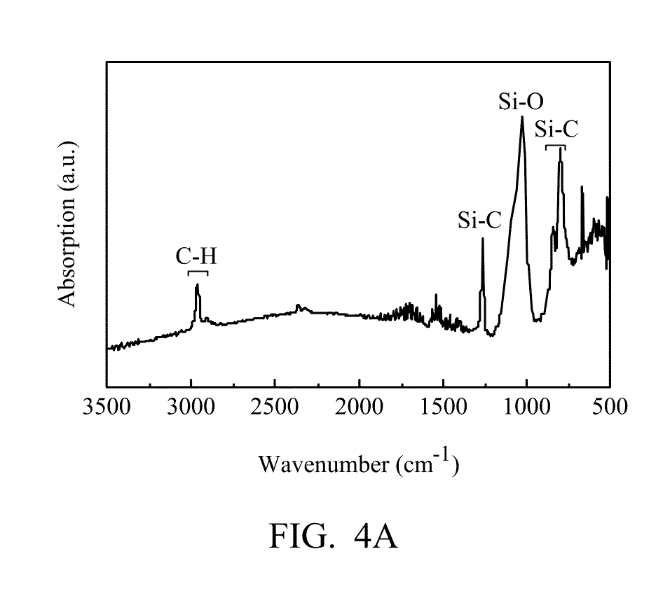

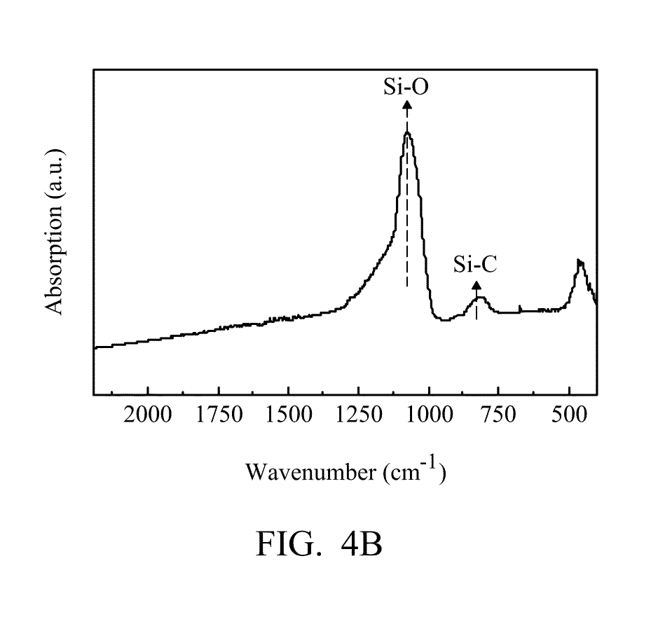

FIGS. 4A and 4B show Fourier transform infrared spectrum of the interposer layers of Examples 1 and 5, respectively. It can be observed from FIG. 4A that the ratio of the Si—C bonds and the Si—O bonds is about 0.3. It can be observed from FIG. 4B that the ratio of the Si—C bonds and the Si—O bonds is about 0.07.

The adhesive attractions of the poly(p-xylylene) films of Examples 1 to 6 were measured by tape according to the ASTM D5539 standard test method (e.g., cutting the coating film the substrate to one hundred squares; adhering a tape onto the coating film; and peeling the tape). The results show that the adhesive attraction of the poly(p-xylylene) film of Examples 1 to 3 to the stainless substrate was rated to 5B level (almost no damage). The adhesive attraction of the poly(p-xylylene) film of Examples 4 and 5 to the stainless substrate was rated to 2B˜4B levels (5%˜35% of squares were damaged). The adhesive attraction of the poly(p-xylylene) film of Example 6 to the stainless substrate was rated to a 0B level (more than 65% of squares were damaged). The results show that the poly(p-xylylene) film has better adhesive attraction to the substrate when the interposer layer is presented with the ratio of the Si—C bonds and the Si—O bonds ranging from 0.3 to 0.8.

### Example 7

A glass substrate was disposed in a vacuum deposition chamber. 100 sccm of Ar was introduced to the deposition chamber and maintained a pressure of the deposition chamber at 60 mTorr. RF plasma of 100 W and 13.56 MHz was applied to the surface of the stainless substrate for 1 minute. 100 sccm of HMDSO was then introduced to the deposition chamber and coated to the surface of the stainless substrate under a pressure of 40 mTorr and RF plasma of 100 W and 13.56 MHz for 10 minutes. An interposer layer was formed. The interposer layer had a thickness of about 120 nm, and a ratio of Si—C bonds and Si—O bonds in the interposer layer was about 0.3.

10 g of a solider powder of p-xylylene dimers was disposed in a vaporizing chamber and heated to 150 degrees Celsius to vaporize the p-xylylene dimers to gas. Afterwards, the gas of p-xylylene was introduced to a thermal cracking chamber that had a temperature of 650 degrees Celsius for being thermal-cracked to monomers. The p-xylylene monomers were then introduced to the deposition chamber that was at room temperature, and a poly(p-xylylene) film was deposited. The poly(p-xylylene) film had a thickness of about 3 μm.

### Example 8

The same operation as in Example 7 was repeated except that the interposer layer was not formed.

### Example 9

The same operation as in Example 7 was repeated except that the glass substrate was replaced with a polyimide substrate.

### Example 10

The same operation as in Example 8 was repeated except that the glass substrate was replaced with a polyimide substrate.

The adhesive attractions of the poly(p-xylylene) films of Examples 7 to 10 were measured by tape according to the ASTM D5539 standard test method. The results show that the adhesive attraction of the poly(p-xylylene) films of Examples 7 and 9 to the stainless substrate were rated to a 5B level (almost no damage). The adhesive attraction of the poly(p-xylylene) films of Examples 8 and 10 to the stainless substrate were rated to a 0B level (more than 65% of squares were damaged).

### Example 11

An OLED substrate, including OLED components on a glass substrate, was disposed in a deposition chamber that had a vacuum environment. 30 sccm of Ar and 40 sccm of HMDSO were introduced to the deposition chamber, and the HMDSO was coated to the surface of the glass substrate under a pressure of 40 mTorr and RF plasma of 400 W and 13.56 MHz. A first barrier layer was formed. The first barrier layer had a thickness of about 50 nm. A ratio of Si—C bonds and Si—O bonds in the first barrier layer was about 0.2. Then, 160 sccm of N₂O and 30 sccm of HMDSO were introduced to the deposition chamber, and the HMDSO was coated to the first barrier layer under a pressure of 20 mTorr and RF plasma of 2000 W and 13.56 MHz. A second barrier layer was formed on the first barrier layer. The second barrier layer had a thickness of about 100 nm. A ratio of Si—C bonds and Si—O bonds in the second barrier layer was about 0.07.

Afterwards, 100 sccm of HMDSO was introduced to the deposition chamber and coated to the surface of the second barrier layer under a pressure of 40 mTorr and RF plasma of 100 W and 13.56 MHz for 10 minutes. An interposer layer was formed over the second barrier layer. The interposer layer had a thickness of about 120 nm. A ratio of Si—C bonds and Si—O bonds in the interposer layer was about 0.3.

10 g of a solider powder of p-xylylene dimers was disposed a vaporizing chamber and heated to 150 degrees Celsius to vaporize the p-xylylene dimers to gas. Afterwards, the gas of p-xylylene was introduced to a thermal cracking chamber that had a temperature of 650 degrees Celsius for being thermal-cracked to monomers. The p-xylylene monomers were then introduced to the deposition chamber that had a chamber temperature, and a poly(p-xylylene) film was deposited. The poly(p-xylylene) film had a thickness of about 3 μm.

30 sccm of Ar and 40 sccm of HMDSO were introduced to the deposition chamber, and the HMDSO was coated to the poly(p-xylylene) film under a pressure of 40 mTorr and RF plasma of 400 W and 13.56 MHz. A third barrier layer was formed. The first barrier layer had a thickness of about 50 nm. A ratio of Si—C bonds and Si—O bonds in the third barrier layer was about 0.2. Then, 160 sccm of N₂O and 30 sccm of HMDSO were introduced to the deposition chamber, and the HMDSO was coated to the third barrier layer under a pressure of 20 mTorr and RF plasma of 2000 W and 13.56 MHz. A second barrier layer was formed on the first barrier layer. The second barrier layer had a thickness of about 100 nm. A ratio of Si—C bonds and Si—O bonds in the second barrier layer was about 0.07.

### Example 12

The same operation as in Example 11 was repeated except that the interposer layer and the poly(p-xylylene) film were not formed.

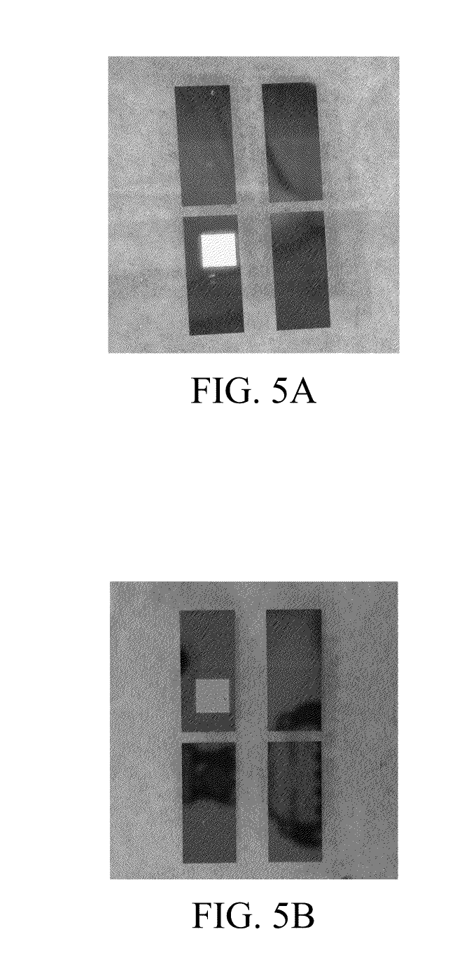

FIGS. 5A and 5B, respectively, show photographs of the OLED devices of Examples 11 and 12 in operation. The photographs clearly show that the OLED device of Example 10 illumined uniformly and had expected brightness even if it was operated in air. It can be concluded that the OLED components can be effectively protected by the poly(p-xylylene) film. In comparison, the OLED device in Example 12 only had a reduced brightness and began to have dark points.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A laminate structure, comprising
a substrate having a surface;
a poly(p-xylylene) film over the surface of the substrate; and
an interposer layer between the substrate and the poly(p-xylylene) film, wherein the interposer layer is bonded to both the substrate and the poly(p-xylylene) film in a covalent manner, wherein a ratio of Si—C bonds and Si—X bonds in the interposer layer is in a range from about 0.3 to about 0.8, wherein X is O or N.

2. The laminate structure as claimed in claim 1, wherein the poly(p-xylylene) film comprises Parylene-C, Parylene-D, Parylene-N, Parylene-F or a combination thereof.

3. The laminate structure as claimed in claim 1, wherein the surface of the substrate comprises a metal surface, a metal oxide surface, a semiconductor surface, a glass surface or a plastic surface.

4. The laminate structure as claimed in claim 3, wherein the metal surface comprises copper, titanium, aluminum, alloys thereof or stainless steel.

5. The laminate structure as claimed in claim 3, wherein the metal oxide surface comprises indium tin oxide, zinc oxide, indium gallium zinc oxide, gallium zinc oxide, aluminum zinc oxide or a combination thereof.

6. The laminate structure as claimed in claim 3, wherein the plastic surface comprises polyimide, poly polyethylene terephthalate, polyethylene naphthalate, polyethersulfone, polycarbonate or a combination thereof.

7. The laminate structure as claimed in claim 1, the poly(p-xylylene) film has a thickness ranging from about 0.2 μm to about 10 μm.

8. The laminate structure as claimed in claim 1, wherein the interposer layer has a thickness ranging from about 30 nm to about 300 nm.

9. The laminate structure as claimed in claim 1, wherein the poly(p-xylylene) film and the interposer layer are bonded in the covalent manner by the following formula: 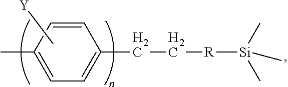
wherein “n” is an integer greater than or equal to 1, Y is Cl or H, and “R” is —(CH₂)ₘ—, wherein “m” is an integer from 0 to 500.

10. A method for forming a laminate structure, comprising
providing a substrate that has a surface;
introducing a silane coupling agent to a deposition chamber for forming an interposer layer over the surface of the substrate by plasma enhanced chemical vapor deposition (PECVD), wherein the gas in the deposition chamber comprises only a silane group agent during the PECVD;
thermal cracking poly(p-xylylene) oligomers to poly(p-xylylene) monomers that carry radicals; and
introducing the poly(p-xylylene) monomers to the deposition chamber to polymerize to a poly(p-xylylene) film, wherein the poly(p-xylylene) film is bonded to the interposer layer in a covalent manner.

11. The method as claimed in claim 10, wherein the flow rate of the silane coupling agent is in a range from about 10 sccm to about 200 sccm.

12. The method as claimed in claim 10, wherein the silane coupling agent comprises hexamethyldisiloxane (HMDSO) or hexamethyldisilazane (HMDS).

13. The method as claimed in claim 10, wherein the poly(p-xylylene) oligomers comprise poly(p-xylylene) dimers.

14. A luminescent device, comprising:
a substrate having a surface;
a luminescent component over the surface of the substrate;
a poly(p-xylylene) film over the surface of the substrate and covering the luminescent component;
an interposer layer between the luminescent component and the substrate, wherein the interposer layer is bonded to both the substrate and the poly(p-xylylene) film in a covalent manner, wherein a ratio of Si—C bonds and Si—X bonds in the interposer layer is in a range from about 0.3 to about 0.8, wherein X is O or N; and
a first barrier layer covering the poly(p-xylylene) film.

15. The luminescent device as claimed in claim 14, wherein the surface of the substrate comprises a metal surface, a metal oxide surface, a semiconductor surface, a glass surface or a plastic surface.

16. The luminescent device as claimed in claim 14, wherein the poly(p-xylylene) film has a thickness ranging from about 0.2 μm to about 10 μm.

17. The luminescent device as claimed in claim 14, wherein the first barrier layer comprises at least one organic sub-layer and/or at least one inorganic sub-layer.

18. The luminescent device as claimed in claim 14, wherein the first barrier layer comprises an organic siloxane layer, wherein a ratio of Si—C bonds and Si—O bonds in the first barrier layer is less than about 0.25.

19. The luminescent device as claimed in claim 14, further comprising a second barrier layer between the luminescent component and the interposer layer, wherein the second barrier layer covers an upper surface and sidewalls of the luminescent component.

20. The luminescent device as claimed in claim 19, wherein the second barrier layer comprises an organic siloxane layer, wherein a ratio of Si—C bonds and Si—O bonds in the second barrier layer is less than about 0.25.
